(19) United States
(12) Patent Application Publication
(10) Pub. No.: US 2018/0331198 A1
(43) Pub. Date: Nov. 15, 2018

(54) THIN OXIDE ZERO THRESHOLD VOLTAGE (ZVT) TRANSISTOR FABRICATION

(71) Applicant: QUALCOMM Incorporated, San Diego, CA (US)

(72) Inventor: Phanikumar KONKAPAKA, San Diego, CA (US)

(21) Appl. No.: 15/709,332

(22) Filed: Sep. 19, 2017

Related U.S. Application Data
(60) Provisional application No. 62/506,535, filed on May 15, 2017.

(51) Int. Cl. H01L 29/49; H01L 27/088; H01L 21/8234; G06F 17/50

(52) U.S. Cl. CPC H01L 29/4966; H01L 27/0886; G06F 17/5081; H01L 21/823431; G06F 17/5045; H01L 21/823493

(57) ABSTRACT

A method of manufacturing a thin gate oxide N-type metal-oxide-semiconductor (NMOS) zero threshold voltage (ZVT) field effect transistor (FET) and an NMOS medium gate oxide native FET with a semiconductor manufacturing process eliminates the addition of halo masks. In one instance, the method includes selecting a gate stack to create the thin gate oxide NMOS ZVT FET or the NMOS medium gate oxide native FET when combined with blocking a P-type well implant and/or blocking a threshold voltage implant. The method also includes fabricating, on a semiconductor substrate, the selected gate stack. The method further includes blocking the P-type well implant and/or blocking the threshold voltage implant to obtain the thin gate oxide NMOS ZVT FET or the NMOS medium gate oxide native FET.

### CROSS-REFERENCE TO RELATED APPLICATION

The present application claims the benefit of U.S. Provisional Patent Application No. 62/506,535, filed on May 15, 2017, and titled “THIN OXIDE ZERO THRESHOLD VOLTAGE (ZVT) TRANSISTOR FABRICATION,” the disclosure of which is expressly incorporated by reference herein in its entirety.

### TECHNICAL FIELD

The present disclosure generally relates to semiconductor fabrication. More specifically, the present disclosure relates to fabrication of a thin oxide zero threshold voltage (ZVT) transistor with a semiconductor manufacturing process.

### BACKGROUND

Integrated circuits and their designs are getting more and more complex. A design cycle may last a year or more and cost millions of dollars. With a long and expensive design cycle, it is important to make appropriate choices for, among others, process technology.

Generally, current technologies providing more compact and functional electronic devices specify semiconductor devices with exact threshold voltages at different threshold voltage levels. Devices of different types are considered, such as, for example, low threshold voltage (LVT) devices, regular threshold voltage (RVT) devices, high threshold voltage (HVT) devices, and super high threshold voltage (SHVT) devices. For example, the threshold voltage level of HVT devices is greater than the threshold voltage of RVT devices by about 80 mV. SHVT devices show a delta in the threshold voltage level relative to RVT devices in the range of about 140-160 mV. These differences or delta in the threshold voltage between the different types of devices, HVT and RVT, SHVT and RVT, may be subjective and different technologies may have different deltas.

Conventionally, complex integrated circuit (IC) processes may be able to produce a great number of LVT devices and RVT devices. However, these complex IC processes may have limitations related to an absence of some types of threshold voltage devices.

### SUMMARY

A of manufacturing a thin gate oxide N-type metal-oxide-semiconductor (NMOS) zero threshold voltage (ZVT) field effect transistor (FET) and an NMOS medium gate oxide native FET with a semiconductor manufacturing process is described. The method may include selecting a gate stack to create the thin gate oxide NMOS ZVT FET or the NMOS medium gate oxide native FET when combined with blocking a P-type well implant and/or blocking a threshold voltage implant. The method also includes fabricating, on a semiconductor substrate, the selected gate stack. The method further includes blocking the P-type well implant and/or blocking the threshold voltage implant to obtain the thin gate oxide NMOS ZVT FET or the NMOS medium gate oxide native FET.

A method of manufacturing a high threshold voltage (HVT) device or a super high threshold voltage (SHVT) device may include fabricating, on a semiconductor substrate, a gate stack that enables a threshold voltage from a metal work function of a semiconductor manufacturing process. The method also includes replacing the gate stack with a different gate stack from the semiconductor manufacturing process to obtain the HVT device or the SHVT device.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 shows a wireless device communicating with a wireless communication system.

FIG. 2 shows a block diagram of the wireless device in FIG. 1, according to an aspect of the present disclosure.

FIG. 3 is an energy band diagram illustrating a metal work function for each different type of transistor.

FIG. 4A shows a front cross-sectional view of one low threshold voltage N-type fin field effect transistor (LVT N-type finFET) according to various exemplary aspects.

FIG. 4B shows a front cross-sectional view of one standard threshold voltage N-type fin field effect transistor (SVT N-type finFET) according to various exemplary aspects.

FIG. 5A depicts a simplified flowchart of a method of manufacturing a thin gate oxide zero threshold voltage (ZVT) transistor and a medium gate oxide native field effect transistor with a semiconductor manufacturing process according to aspects of the present disclosure.

FIG. 5B depicts a simplified flowchart of a method of manufacturing a high threshold voltage (HVT) or super high threshold voltage (SHVT) device according to aspects of the present disclosure.

FIG. 6 is a block diagram showing an exemplary wireless communication system in which a configuration of the disclosure may be advantageously employed.

FIG. 7 is a block diagram illustrating a design workstation used for circuit, layout, and logic design of the transistor according to aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts. As described herein, the use of the term “and/or” is intended to represent an “inclusive OR”, and the use of the term “or” is intended to represent an “exclusive OR”.

Mobile radio frequency (RF) chip designs (e.g., transceivers) have migrated to a deep sub-micron process node due to cost and power consumption considerations. The design complexity of mobile RF transceivers is further complicated by added circuit function to support communication enhancements. Further design challenges for mobile RF chip designs include analog/RF performance considerations, including mismatch, noise, and other performance considerations.

The mobile RF chip design may be fabricated in accordance with a three dimensional fin field effect transistor (finFET) process or any other process technology such as planar or metal-oxide-semiconductor technologies that implement multiple gate stacks with different resistances. The process technology may be a fourteen nanometer (14 nm) finFET process (e.g., 14 low power compact (LPC)-radio frequency (RF) process technology, which is a metal (or conductive material) work function based process technology with dual gate stacks). An integrated circuit (IC) may be formed based on the process technology. The process technology may enable multiple (e.g., two) types of gate stacks instead of only one type of gate stack. For example, one or more first type transistors of the IC may have a first gate stack with a first resistance. Also, one or more second type transistors of the IC may have a second gate stack with a second resistance that is higher than the first resistance.

In one aspect, the different types of transistors include an N-type metal-oxide-semiconductor (NMOS) low threshold voltage field effect transistor (LVTN FET), a P-type metal-oxide-semiconductor (PMOS) low threshold voltage field effect transistor (LVTP FET), an NMOS regular threshold voltage field effect transistor (RVTN FET), a PMOS regular threshold voltage field effect transistor (RVTP FET), an NMOS high threshold voltage field effect transistor (HVTN FET), a PMOS high threshold voltage field effect transistor (HVTP FET), an NMOS analog low threshold voltage field effect transistor (ALVTN FET), a PMOS analog low threshold voltage field effect transistor (ALVTP FET), etc. For example, the first type of transistors may be the ALVTN FETs and the second type of transistors may be the RVTN FETs.

Differences exist between each gate stack of a dual gate stack (e.g., one for ALVT and one for RVT) that are associated with different process technologies. However, differences also exist between gate stacks of a common process technology (e.g., ALVTN and ALVTP or RVTN and RVTP). For example, the ALVTN gate stack, which is an NMOS gate stack, is different from the ALVTP gate stack, which is a PMOS gate stack. Thus, a dual gate stack may include more than two gate stacks. For example, a dual gate stack may include four gate stacks in a technology offering. These dual gate stacks of different ALVTN and RVTN may be used for the mobile RF chip designs. Other gate stacks such as the ALVTP/RVTP gate stacks are indeed present in the flow and are different from each other and the ALVTN/RVTN gate stacks.

Conventional process technology that enables multiple (e.g., two) types of gate stacks has limited availability of process technologies for the gate stacks. For example, conventional dual stack process technology does not include thin gate oxide zero voltage (ZVT) field effect transistors, medium thickness gate oxide native field effect transistors, high threshold voltage (HVT) and/or super high threshold voltage (SHVT) field effect transistors. For example, the 14 LPC-RF process technology does not include ZVT FETs.

One way to achieve HVT and SHVT in a process technology is by halo implanting processes. For example, a 14 nanometer process technology (e.g., 14 low power plus (LPP) process technology, which is a digital based process technology with a single gate stack), includes halo based RVT, LVT, HVT, and SHVT devices. For example, halo implantation processes are conventionally performed for adjusting the threshold voltage when fabricating modern semiconductor devices, such as MOS transistors, with short channels (e.g., less than 50 nm channel length). The result is a complex process flow, even posing the risk of introducing unacceptably high variations of the threshold voltage across the wafer due to the inclusion of new processes. Moreover, the halo implanting process has a drawback of introducing additional masks to the process flow, thereby increasing cost. In addition, halo based Vt setting scheme transistors have degraded Idoff versus Ieff performance compared to FETs with a metal work function based Vt setting scheme due to mobility degradation. Idoff is a transistor off-state leakage current and Ieff or Idsat is an on-state current of the transistor.

Aspects of the present disclosure leverage multiple (e.g., two) types of gate stacks of existing process technology to form the thin gate oxide ZVT (or core ZVT) field effect transistors, medium thickness native gate oxide field effect transistors, HVT field effect transistors, and/or SHVT field effect transistors without adding halo masks. For example, the aspects of the present disclosure leverage an ALVT gate stack that is developed for the 14 nanometer LPC-RF process technology. The 14 LPC-RF process technology, which is a derivative of the 14 LPP process technology, introduces one or more additional gate stacks including the ALVT gate stack. However, neither 14 LPP process technology nor the 14 LPC-RF process technology include the thin gate oxide zero voltage (ZVT) field effect transistors, medium thickness gate oxide native field effect transistors, high threshold voltage (HVT) and/or super high threshold voltage (SHVT) field effect transistors.

The aspects of the present disclosure swap gate stacks using existing masks in the process flow or block certain implants in the semiconductor manufacturing process to achieve the desirable transistors or devices. For example, the HVT and SHVT devices are obtained in a 14 nanometer LPC-RF process technology without adding any halo masks, but by swapping gate stacks of existing devices (e.g., transistors) with a different gate stack. In addition, a thin gate oxide zero threshold voltage (ZVT) field effect transistor (FET) may also be achieved with a semiconductor manufacturing process by starting with a selected low voltage gate stack and blocking implants (e.g., P-type well and threshold voltage implants). The ZVT FET may be an NMOS ZVT FET. The NMOS ZVT FET and the NMOS medium gate oxide native FET may be a finFET.

In one aspect, a gate stack that enables a low threshold voltage (e.g., a lowest threshold voltage) NFET from a low metal work function (e.g., a lowest metal work function) of the semiconductor manufacturing process is fabricated on a semiconductor substrate. The substrate may be a semiconductor substrate such as silicon, silicon germanium, gallium arsenide, or other suitable semiconductor material. The substrate includes other features such as various doped regions such as a P-type well or an N-type well. To vary the threshold voltage of the transistor, an amount of a dopant material used to form the wells of the transistor is varied.

In one aspect, a P-type well implant and/or a threshold voltage implant are blocked from an N-type analog low threshold voltage device. This aspect further includes sharing a low doped drain associated with the gate stack (e.g., ALVT gate stack) that enables the lowest threshold voltage. The gate stack that enables the lowest threshold voltage from the lowest metal work function may include a gate stack of an N-type analog low threshold voltage (ALVTN) device. Alternatively, a new low doped drain mask may be introduced to the process flow to independently control the lowest threshold voltage (e.g., ZVT).

Another aspect of the disclosure achieves a medium gate oxide native field effect transistor with a semiconductor manufacturing process. In this aspect, a gate stack that enables the lowest threshold voltage from the lowest metal work function of the semiconductor manufacturing process is fabricated on the semiconductor substrate. In this aspect, the P-type well implant and/or a threshold voltage implant are blocked from the medium gate oxide native field effect transistor. This aspect further includes sharing a low doped drain (LDD) of the gate stack that enables a lowest threshold voltage. A mask of the medium gate oxide native field effect transistor is added for an LDD of the medium gate oxide native field effect transistor.

Yet another aspect of the disclosure achieves a high threshold voltage (HVT) or super high threshold voltage (SHVT) device. In this aspect, a gate stack that enables a threshold voltage from a metal work function of a semiconductor manufacturing process is fabricated on the semiconductor substrate. The gate stack is replaced with a different gate stack from the semiconductor manufacturing process to achieve the HVT or the SHVT device. The different gate stack may include a gate stack of a P-type regular threshold voltage device. In one aspect, NHVT is achieved by replacing gate stack of ALVTNFET with the gate stack of RVTPFET as shown in Table 3. The HVT or the SHVT device is achieved without additional masks (e.g., halo masks).

The aspects of the present disclosure (e.g., ZVT FET and medium gate oxide native FET) support low threshold voltages for field effect transistors that enable a pass device and improve voltage head room in low dropout (LDO) regulators (LDOs). For example, when a transistor is used as pass device, it transfers a logic state from drain to source, but at the expense of Vt difference. This means that a voltage level at the destination is lower by Vt of the pass transistor because the pass transistor experiences a voltage drop. To avoid this voltage drop, use of a ZVT is desirable because the Vt of the ZVT is close to zero and a voltage drop between a source and a drain of the ZVT is negligible (e.g., with close to no voltage level difference).

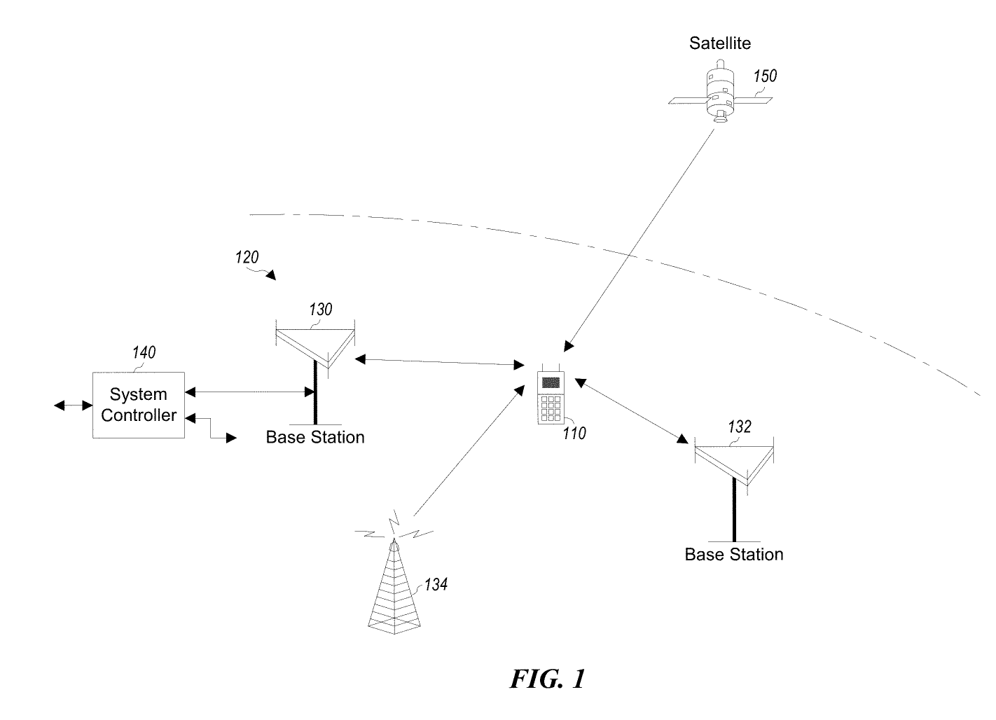

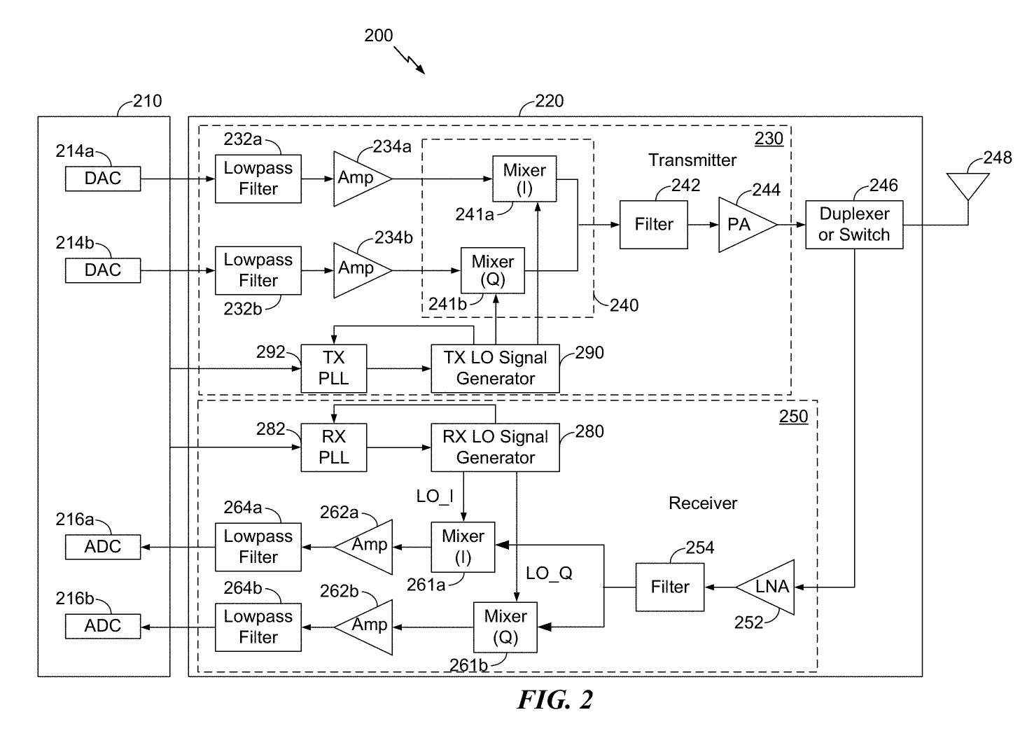

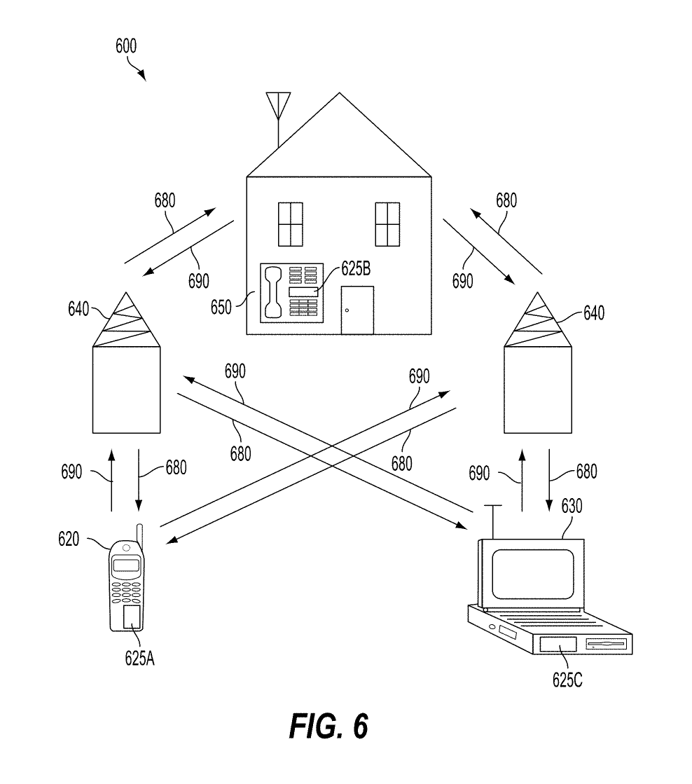

The devices achieved from the aspects of the present disclosure may be implemented in the systems of FIGS. 1 and 6. More specifically, the achieved devices may be implemented in the wireless device of FIG. 2.

FIG. 1 shows a wireless device 110 communicating with a wireless communication system 120. The wireless communication system 120 may be a 5G system, a long term evolution (LTE) system, a code division multiple access (CDMA) system, a global system for mobile communications (GSM) system, a wireless local area network (WLAN) system, or some other wireless system. A CDMA system may implement wideband CDMA (WCDMA), time division synchronous CDMA (TD-SCDMA), CDMA2000, or some other version of CDMA. For simplicity, FIG. 1 shows the wireless communication system 120 including two base stations 130 and 132 and one system controller 140. In general, a wireless system may include any number of base stations and any number of network entities.

A wireless device 110 may be referred to as a user equipment (UE), a mobile station, a terminal, an access terminal, a subscriber unit, a station, etc. The wireless device 110 may also be a cellular phone, a smartphone, a tablet, a wireless modem, a personal digital assistant (PDA), a handheld device, a laptop computer, a Smartbook, a netbook, a cordless phone, a wireless local loop (WLL) station, a Bluetooth device, etc. The wireless device 110 may be capable of communicating with the wireless communication system 120. The wireless device 110 may also be capable of receiving signals from broadcast stations (e.g., a broadcast station 134), signals from satellites (e.g., a satellite 150) in one or more global navigation satellite systems (GNSS), etc. The wireless device 110 may support one or more radio technologies for wireless communication such as 5G, LTE, CDMA2000, WCDMA, TD-SCDMA, GSM, 802.11, etc.

The wireless device 110 may support carrier aggregation, which is operation on multiple carriers. Carrier aggregation may also be referred to as multi-carrier operation. According to an aspect of the present disclosure, the wireless device 110 may be able to operate in low-band from 698 to 960 megahertz (MHz), mid-band from 1475 to 2170 MHz, and/or high-band from 2300 to 2690 MHz, ultra-high band from 3400 to 3800 MHz, and long-term evolution (LTE) in LTE unlicensed bands (LTE-U/LAA) from 5150 MHz to 5950 MHz. Low-band, mid-band, high-band, ultra-high band, and LTE-U refer to five groups of bands (or band groups), with each band group including a number of frequency bands (or simply, “bands”). For example, in some systems each band may cover up to 200 MHz and may include one or more carriers. For example, each carrier may cover up to 40 MHz in LTE. Of course, the range for each of the bands is merely exemplary and not limiting, and other frequency ranges may be used. LTE Release 11 supports 35 bands, which are referred to as LTE/UMTS bands and are listed in 3GPP TS 36.101. The wireless device 110 may be configured with up to 5 carriers in one or two bands in LTE Release 11.

FIG. 2 shows a block diagram of an exemplary design of a wireless device 200, such as the wireless device 110 shown in FIG. 1. FIG. 2 shows an example of a transceiver 220, which may be a wireless transceiver (WTR). In general, the conditioning of the signals in a transmitter 230 and a receiver 250 may be performed by one or more stages of amplifier(s), filter(s), upconverters, downconverters, and the like. These circuit blocks may be arranged differently from the configuration shown in FIG. 2. Furthermore, other circuit blocks not shown in FIG. 2 may also be used to condition the signals in the transmitter 230 and receiver 250. Unless otherwise noted, any signal in FIG. 2, or any other illustrations in the drawings, may be either single-ended or differential. Some circuit blocks in FIG. 2 may also be omitted.

In the example shown in FIG. 2, the wireless device 200 generally includes the transceiver 220 and a data processor 210. The data processor 210 may include a memory (not shown) to store data and program codes, and may generally include analog and digital processing elements. The transceiver 220 may include the transmitter 230 and receiver 250 that support bi-directional communication. In general, the wireless device 200 may include any number of transmitters and/or receivers for any number of communication systems and frequency bands. All or a portion of the transceiver 220 may be implemented on one or more analog integrated circuits (ICs), radio frequency (RF) integrated circuits (RFICs), mixed-signal ICs, and the like.

A transmitter or a receiver may be implemented with a super-heterodyne architecture or a direct-conversion architecture. In the super-heterodyne architecture, a signal is frequency-converted between radio frequency and baseband in multiple stages (e.g., from radio frequency to an intermediate frequency (IF) in one stage, and from intermediate frequency to baseband in another stage for a receiver). In the direct-conversion architecture, a signal is frequency-converted between radio frequency and baseband in one stage. The super-heterodyne and direct-conversion architectures may use different circuit blocks and/or have different requirements. In the example shown in FIG. 2, the transmitter 230 and the receiver 250 are implemented with the direct-conversion architecture.

In a transmit path, the data processor 210 processes data to be transmitted. The data processor 210 also provides in-phase (I) and quadrature (Q) analog output signals to the transmitter 230 in the transmit path. In an exemplary aspect, the data processor 210 includes digital-to-analog converters (DACs) 214a and 214b for converting digital signals generated by the data processor 210 into the in-phase (I) and quadrature (Q) analog output signals (e.g., I and Q output currents) for further processing.

Within the transmitter 230, lowpass filters 232a and 232b filter the in-phase (I) and quadrature (Q) analog transmit signals, respectively, to reduce undesired images caused by the prior digital-to-analog conversion. Amplifiers (Amp) 234a and 234b amplify the signals from lowpass filters 232a and 232b, respectively, and provide in-phase (I) and quadrature (Q) baseband signals. An upconverter 240 including upconversion mixers 241a and 241b upconverts the in-phase (I) and quadrature (Q) baseband signals with in-phase (I) and quadrature (Q) transmit (TX) local oscillator (LO) signals from a TX LO signal generator 290 to provide an upconverted signal. A filter 242 filters the upconverted signal to reduce undesired images caused by the frequency upconversion as well as interference in a receive frequency band. A power amplifier (PA) 244 amplifies the signal from filter 242 to obtain the desired output power level and provides a transmit radio frequency signal. The transmit radio frequency signal is routed through a duplexer/switch 246 and transmitted via an antenna 248.

In a receive path, the antenna 248 receives communication signals and provides a received radio frequency (RF) signal, which is routed through the duplexer/switch 246 and provided to a low noise amplifier (LNA) 252. The duplexer/switch 246 is designed to operate with a specific receive (RX) to transmit (TX) (RX-to-TX) duplexer frequency separation, such that RX signals are isolated from TX signals. The received RF signal is amplified by the LNA 252 and filtered by a filter 254 to obtain a desired RF input signal. Downconversion mixers 261a and 261b mix the output of the filter 254 with in-phase (I) and quadrature (Q) receive (RX) LO signals (i.e., LO_I and LO_Q) from an RX LO signal generator 280 to generate in-phase (I) and quadrature (Q) baseband signals. The in-phase (I) and quadrature (Q) baseband signals are amplified by amplifiers 262a and 262b and further filtered by lowpass filters 264a and 264b to obtain in-phase (I) and quadrature (Q) analog input signals, which are provided to the data processor 210. In the exemplary configuration shown, the data processor 210 includes analog-to-digital converters (ADCs) 216a and 216b for converting the analog input signals into digital signals for further processing by the data processor 210.

In FIG. 2, the transmit local oscillator (TX LO) signal generator 290 generates the in-phase (I) and quadrature (Q) TX LO signals used for frequency upconversion, while a receive local oscillator (RX LO) signal generator 280 generates the in-phase (I) and quadrature (Q) RX LO signals used for frequency downconversion. Each LO signal is a periodic signal with a particular fundamental frequency. A phase locked loop (PLL) 292 receives timing information from the data processor 210 and generates a control signal used to adjust the frequency and/or phase of the TX LO signals from the TX LO signal generator 290. Similarly, a PLL 282 receives timing information from the data processor 210 and generates a control signal used to adjust the frequency and/or phase of the RX LO signals from the RX LO signal generator 280.

The wireless device 200 may support carrier aggregation and may (i) receive multiple downlink signals transmitted by one or more cells on multiple downlink carriers at different frequencies, and/or (ii) transmit multiple uplink signals to one or more cells on multiple uplink carriers. For intra-band carrier aggregation, the transmissions are sent on different carriers in the same band. For inter-band carrier aggregation, the transmissions are sent on multiple carriers in different bands. Those skilled in the art will understand, however, that aspects described herein may be implemented in systems, devices, and/or architectures that do not support carrier aggregation.

Metal-oxide-semiconductor field effect transistors (MOSFETs or FETs) represent one important type of circuit element that substantially determines performance of the integrated circuits. A difference between the NMOS and PMOS transistors is based on the type of dopants used to create the source/drain regions of the devices. Complementary metal-oxide-semiconductor technology or products refers to integrated circuit products that are manufactured using both NMOS and PMOS transistor devices.

Current flow through the FET is controlled by controlling the voltage applied to the gate electrode. In manufacturing modern integrated circuit products, transistor devices are sometimes intentionally formed so as to exhibit different threshold voltage levels. In general, a transistor having a relatively lower threshold voltage will operate at a higher switching speed than that of a corresponding transistor with a relatively higher threshold voltage level.

Device designers have employed several techniques to intentionally change the threshold voltage levels of transistor devices. One technique simply involves changing the gate length (e.g., the distance between the source region and the drain region of the transistor). However, device dimensions have decreased to the point where gate lengths are so small that manufacturing devices with ever smaller gate lengths is very challenging, time-consuming, and expensive.

Another technique to form transistor devices with differing threshold voltage levels simply involves making gate stacks of different materials having different work function values so as to ultimately achieve the desired variation in the threshold voltage levels of the devices. However, this technique is limited by a process technology. The term “work function” may refer to a minimum energy to remove an electron from a surface of a metal or conductive material. The work function of a metal may be a constant characteristic of that metal material and it is usually measured in electron-volts (eV).

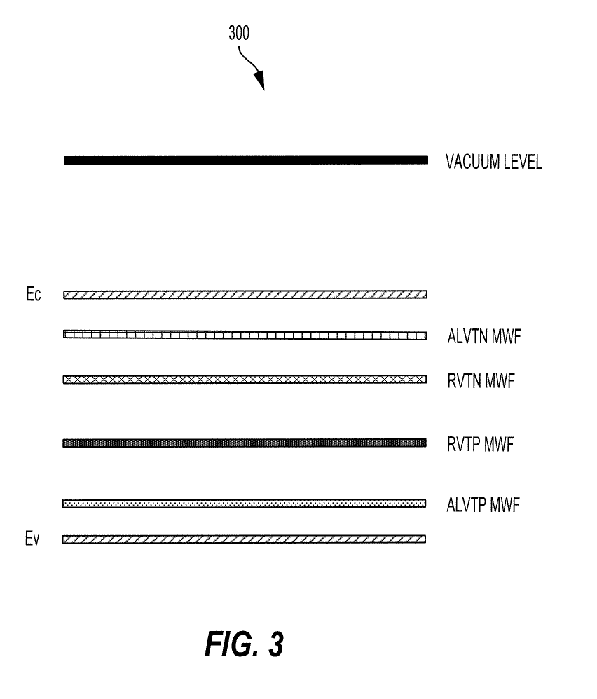

FIG. 3 is an energy band diagram 300 illustrating a metal work function for each different type of transistor. The energy band diagram 300 includes a vacuum level, a conduction band (Ec) and a valence band (Ev). The energy band diagram may represent gate stacks of the 14 LPC-RF process technology. A significant number of halo/low doped drain masks are eliminated from the 14 LPC-RF process technology relative to the 14 LPP process technology to achieve cost reduction. Moreover, the 14 LPC-RF process technology includes an additional gate stack to enable ALVTN and ALVTP. The metal work function of each gate stack of the 14 LPC-RF process technology is set to anchor at a specific threshold voltage for ALVTN, ALVTP, RVTN, and RVTP.

FIG. 3 illustrates where the metal work functions are expected to be set in the 14 LPC-RF process technology. For example, the energy band diagram 300 illustrates where the metal work functions are expected to be set for each different type of transistor to modulate the threshold voltages (Vth). The metal work function is measured from a vacuum level. Thus, a metal work function (Φm) is higher as a distance from the vacuum level increases. An energy difference between a metal gate Fermi energy and vacuum level corresponds to the metal work function.

The work function of a metal is a constant characteristic of that metal material and it is measured in electron-volts (eV). For example, in CMOS implementations using a silicon substrate, a metal work function having a work function near the conduction band (Ec) edge of silicon is specified for NMOS type devices. For example, energy bands representing the metal work function of N-type devices, ALVTN and RVTN, are near the conduction band (Ec). Alternatively, a different metal work function having a work function near the valance band (Ev) edge of silicon is specified for PMOS devices. Thus, energy bands representing the metal work function of P-type devices, ALVTP and RVTP, are near the valance band (Ev).

Two types of gate stacks may be specified for a process technology. For example, a stack of suitable materials corresponding to a work function for the PMOS devices and a different stack of materials corresponding to a work function for the NMOS devices. The PMOS devices provides a flat band voltage closer to the valence band edge of the material of the channel of the PMOS devices, and the gate stack for the NMOS devices provides a flat band voltage closer to the conduction band edge of the material of the channel of the NMOS devices.

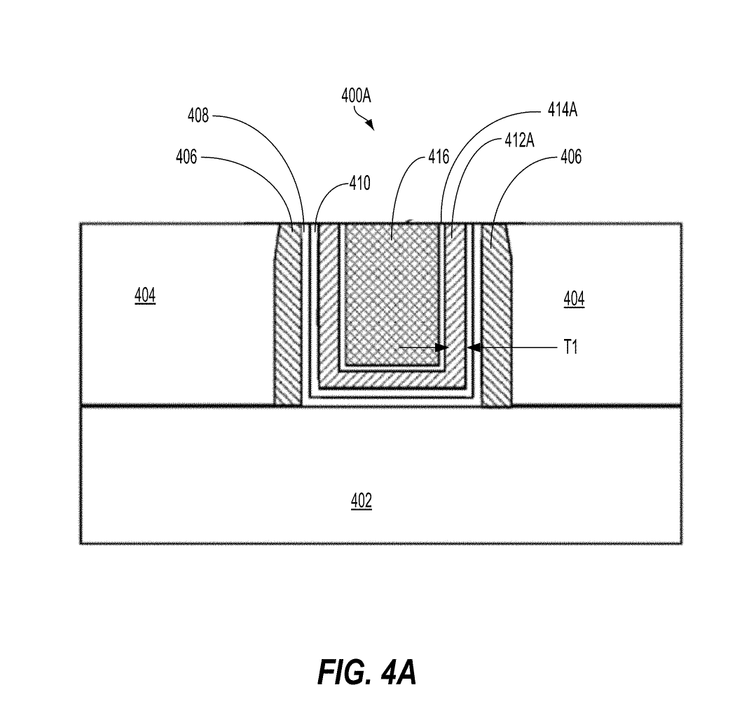

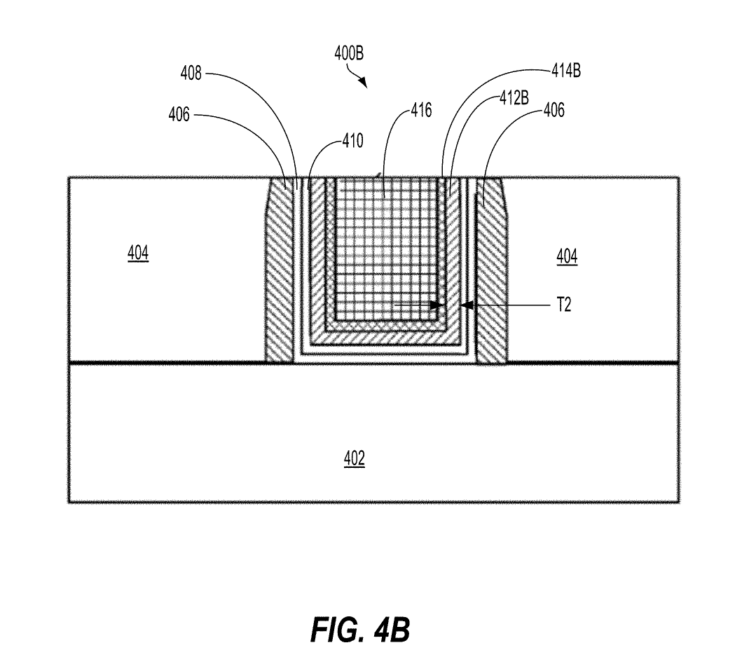

Devices of different types are considered, such as, for example, low threshold voltage (LVT) devices, regular threshold voltage (RVT) devices, high threshold voltage (HVT) devices, and super high threshold voltage (SHVT) devices. Examples of simplified fabrication of NMOS finFETs using a same starting structure are illustrated in FIGS. 4A and 4B.

FIG. 4A shows a front cross-sectional view of one low threshold voltage N-type fin field effect transistor (LVT N-type finFET) 400A, according to various exemplary aspects. The LVT N-type finFET 400A has a fin 402, only a portion of which is visible in FIG. 4A. The LVT N-type finFET 400A may also include a source region (not visible in FIG. 4A) and a drain region (not visible in FIG. 4A).

The LVT N-type finFET 400A includes an inter-level dielectric layer (ILD0) 404, spacers 406, which can form opposing sides of a channel in which a portion of a gate stack is visible. The gate stack may include a high-K dielectric layer 408, a capping layer 410, a work-function metal layer 412A, a barrier layer 414A, and a gate electrode metal 416. The high-K dielectric layer 408 may be formed, for example, of hafnium oxide (HfO2). The capping layer 410 may be formed, for example, of titanium nitride (TiN). The work-function metal layer 412A may be formed of titanium aluminum (TiAl). The barrier layer 414A may be formed, for example, of TiN. The work-function metal layer 412A has a thickness T1.

FIG. 4B shows a front cross-sectional view of one standard threshold voltage N-type fin field effect transistor (SVT N-type finFET) 400B according to various exemplary aspects. For illustrative purposes, the labelling and numbering of the devices and features of FIG. 4B are similar to those of FIG. 4A.

Comparing FIG. 4B and FIG. 4A, there is a difference in a thickness of a work-function metal layer 412B of FIG. 4B, which is illustrated by a thickness T2, and a thickness of the work-function metal layer 412A, which is illustrated by the thickness T1. For example, the thickness T2 of the work-function metal layer 412B of the SVT N-type finFET 400B is more than the thickness T1 of the work-function metal layer 412A of the LVT N-type finFET 400A. The second structural difference is a barrier layer 414B of the SVT N-type finFET 400B, which can be an oxide of the metal forming the work-function metal layer 412B, as opposed to barrier layer 414A of the LVT N-type finFET 400A. These differences can provide an upward tuning of threshold voltage (Vt), for the SVT N-type finFET 400B relative to the Vt of the LVT N-type finFET 400A.

In finFET technology, for example, P-type well implanting or doping is very low (e.g., ˜5e15/cm3) and usually within an order of P-type substrate doping (e.g., ˜4.5e14/cm3). The low doping is specified to provide mobility and to reduce variations in a threshold voltage of the device. Blocking the P-type well implant reduces threshold voltage of a gate stack of a selected device. However, such blocking may be limited by the different types of gate stacks available to a process technology.

For example, a gate stack metal work function for the 14 LPP process technology is anchored at a low voltage threshold (LVT). Anchoring at LVT sets a limit on the lowest threshold voltage (Vt) that can be achieved for the process technology through the metal work function of the gate stack. For example, a gate length Lg=80 nm may result in a saturated threshold voltage (Vtsat) of approximately one hundred and sixty millivolts (˜160 mV) for N-type LVT (LVTN). Thus, even when the P-type well doping is blocked for LVTN, an estimated maximum doping reduction is approximately in an order of thirty to forty millivolts (30-40 mV). This reduction is a technical limitation of the gate stack metal work function for 14 LPP process technology to reach a saturated threshold voltage below one hundred millivolts (100 mV).

A further reduction in the threshold voltage of a gate stack, however, can be achieved with the 14 LPC-RF process technology, which enables additional gate stacks with lower saturated threshold voltages. For example, the 14 LPC-RF process technology enables a second gate stack to form the ALVTN/P transistor with a threshold voltage (Vt) of approximately seventy millivolts (˜70 mV) for a gate length of fourteen nanometers (14 nm).

Aspects of the present disclosure leverage multiple (e.g., two) types of gate stacks of existing process technology (e.g., 14 LPC-RF process technology) to form thin gate oxide ZVT (or core ZVT) field effect transistors, medium thickness gate oxide field effect transistors, HVT field effect transistors, and/or SHVT field effect transistors without adding halo masks.

For example, Table 1 illustrates alternative implementations for achieving ZVT FETs. In one aspect, a gate stack of a starting threshold voltage device (e.g., ALVTN, RVTN, LVTN, ALVTP, RVTP, or LVTP device) of a metal work function based process technology with dual gate stacks is leveraged to achieve ZVT. The gate stack of the starting threshold voltage device may be a high-k metal gate stack. The threshold voltage of the resulting ZVT FET may be based on the starting threshold voltage device. For example, the ZVT FET may have a threshold voltage of zero (0) volts when the starting threshold voltage device is an N-type regular threshold voltage (RVTN) device. Alternatively, the ZVT FET may have a threshold voltage of negative one hundred (−100) millivolts when the starting threshold voltage device is an ALVTN device.

To achieve the proposed ZVT FET, starting with an ALVTN or RVTN device, the threshold voltage is lowered further in accordance with two implementations. One of the implementations includes blocking a P-type well implant and/or blocking a threshold voltage implant from a selected gate stack of the ALVTN or RVTN device, as illustrated in column one of Table 1 to achieve ZVT1. The other implementation includes blocking a P-type well implant and/or blocking a threshold voltage implant from the selected gate stack of the ALVTN or RVTN device as well as sharing an N type low doped drain (LDD)(XW) of the selected gate stack, as illustrated in column two of Table 1 to achieve ZVT2. These implementations can be achieved without introducing additional masks or introducing a new low doped drain mask to independently control the threshold voltage.

TABLE 1
14LPC-RF

| ZVT1 | ZVT1 |
|---|---|
| Use ALVTN gate stack | Use ALVTN gate stack |
| Block Pwell implant and/or Vth | Block Pwell implant and/or Vth |
| implant ALVTN | implant ALVTN |
| | Add XW (share LDD with ALVTN) |

Table 2 illustrates different implementations for achieving medium thickness gate oxide field effect transistors (e.g., NMOS) by leveraging multiple (e.g., two) types of gate stacks of an existing process technology (e.g., 14 LPC-RF process technology). The NMOS medium gate oxide native FET may be formed by selecting a gate stack of a starting threshold voltage device (e.g., ALVTN, RVTN, LVTN, ALVTP, RVTP, or LVTP device) of a metal work function based process technology with dual gate stacks in combination with blocking a P-type well implant and/or blocking a threshold voltage implant. In one aspect, the gate stack of the starting threshold voltage device may be a high-k metal gate stack.

A first NMOS medium gate oxide native FET (e.g., EG native 1) is formed by selecting a MWF (metal work function) metal and a gate conductor stack of an ALVTN device and blocking the P-type well implant and/or the threshold voltage implant from a low doped drain of the NMOS medium gate oxide native FET. A second NMOS medium gate oxide native FET (e.g., EG native 2) is formed by selecting a MWF metal and a gate conductor stack of an ALVTN device, and blocking the P-type well implant and/or the threshold voltage implant from a low doped drain of the NMOS medium gate oxide native FET. The process also includes sharing a low doped drain (LDD) of the ALVTN device. The second NMOS medium gate oxide native FET (e.g., EG native 2) is formed without introducing additional masks or introducing a new low doped drain mask to independently control the threshold voltage of the second NMOS medium gate oxide native FET.

A third NMOS medium gate oxide native FET (e.g., EG native 3) is formed by selecting a MWF metal and a gate conductor stack of an ALVTN device, and blocking the P-type well implant and/or the threshold voltage implant from a low doped drain of the medium gate oxide native NMOS FET. The process also adds a mask of the NMOS medium gate oxide native FET for a low doped drain of the NMOS medium gate oxide native FET (GN mask) 4.

TABLE 2
14LPC-RF

| | | EG Native 3 |
|---|---|---|
| EG Native 1 | EG Native 2 | (1 mask adder) |
| Use ALVTN MWF | Use ALVTN MWF | Use ALVTN MWF metal + |
| metal + gate | metal + gate | gate conductor stack |
| conductor stack | conductor stack | |
| Block P-type well | Block P-type well | Block P-type well implant |
| implant and/or | implant and/or | and/or Vth implant from |
| Vth implant | Vth implant | EGN |
| from EGN | from EGN | |
| | Add XW | Add GN mask for EG LDD |
| | (share LDD with | |
| | ALVTN) | |

Table 3 illustrates a proposed high voltage device (e.g., HVT and SHVT) that is manufactured based on replacing a starting gate stack of a parent device with a different gate stack of a semiconductor manufacturing process. For example, the proposed high voltage device may be obtained without adding halo masks by swapping gate stacks of existing devices with a different gate stack. The proposed aspect may be achieved with a metal work function based process technology with dual gate stacks.

For example, to achieve an NMOS or N-type HVT (HVTN) device, starting with a selected gate stack of an ALVTN device, replace the selected gate stack of the ALVTN device with a gate stack of a P-type or PMOS regular threshold (RVTP) device. By swapping an ALVTN gate stack with a RVTP gate stack, an HVTN gate stack may be achieved due to metal work function differences between ALVTN and RVTP gate stacks. The HVTN device may be achieved with no additional masks. The regular threshold voltage (RVT) device may otherwise be referred to as a standard threshold voltage (SVT) device or other suitable name. For example, the RVT may be approximately 230-260 millivolts (mV) for a 0.8 V supply voltage process. It is noted that this voltage may vary depending on parameters including process, doping, gate length, supply voltage, etc. The HVT may be higher relative to the RVT. For example, the HVT may be approximately 350 mV for a 0.8 V supply voltage process. The ALVT may be lower relative to the RVT and the HVT. For example, the ALVT may be approximately 70-90 mV for a 0.8 V supply voltage process.

TABLE 3

| | | | | |
|---|---|---|---|---|
| Proposed device | HVTN | SHVTN | HVTP | SHVTP |
| Parent device | ALVTN | ALVTN | RVTP | RVTP |
| Replace gate stack of parent | RVTP | ALVTP | RVTN | ALVTP |
| device with this device's gate stack | | | | |
| to arrive at proposed device | | | | |

To achieve an N-type super high threshold voltage (SHVTN) device, starting with a selected gate stack of an ALVTN device, replace the gate stack of the ALVTN device with a gate stack of an ALVTP device. To achieve a HVTP device, starting with a selected gate stack of a RVTP device, replace the selected gate stack of the RVTP device with a gate stack of an RVTN device. To achieve a P-type super high threshold voltage (SHVTP) device, starting with a selected gate stack of an RVTP device, replace the gate stack of the RVTP device with a gate stack of an ALVTP device.

The HVT device and the SHVT device may be achieved without additional masks specific to the HVT device and the SHVT device. For example, existing masks associated with the RVT and/or the ALVT devices are used to achieve the HVT device and the SHVT device.

The threshold voltage (Vt) setting for various types of transistors for the 14 LPC-RF process technology is based on a metal work function. For example, the threshold voltage setting scheme for the 14 LPC-RF process technology relies primarily on a metal work function modulation to achieve different threshold voltages (Vth) for RVTN and ALVTN.

The threshold voltage equals the sum of the flatband voltage, twice the bulk potential and the voltage across the oxide due to the depletion layer charge, or:

$${V}_{T} = {V}_{FB} + 2 {φ}_{F} + \frac{\sqrt{2 \text{?} qN \text{?} ( 2 {φ}_{F} + {V}_{SB} ) }}{{C}_{ox}} \\ \text{?} \text{indicates text missing or illegible when filed} \qquad ( 7.4 .1 )$$

where the flatband voltage, V_{FB}, is given by:

$$\begin{matrix}{V}_{FB} = {Φ}_{MZ} - \frac{{Q}_{f}}{{C}_{ox}} - \frac{1}{{C}_{ox}} – {\int }_{0}^{t \text{?}} \frac{x}{{x}_{ox}} {ρ}_{ox} ( x ) dx \\ With & ( 7.4 .2 ) \\ {Φ}_{MZ} = {Φ}_{M} - {Φ}_{S} = {Φ}_{M} - ( χ + \frac{{E}_{g}}{2 q} + {φ}_{F} ) \\ and & ( 7.4 .3 ) \\ {φ}_{F} = {V}_{t} ln \frac{{N}_{a}}{{n}_{i}} \cdot p - substrate \\ \text{?} \text{indicates text missing or illegible when filed} & ( 7.4 .4 )\end{matrix}$$

where
Φm is a metal work function (MWF);
Φs is a semiconductor work function;
Φms is a metal-semiconductor work function difference Φm−Φs;
Φf is a potential to equalize a shift in Fermi level from intrinsic to doped;
V_{FB} is a flat band voltage;
Cₒₓ is a capacitance of the silicon depletion layer;
Qf is a fixed charge in the oxide;
ρₒₓ(x) is a charge distribution density within a gate oxide;
Vsb is given by source voltage (Vsource)−body voltage (Vbody);
Tₒₓ is the oxide thickness;
εs is a permittivity of silicon;
Na is an acceptor concentration in a substrate;
χ is an electron affinity;
Eg is an energy bandgap of Silicon; and
q is a charge of an electron.

Thus, the metal work function can be modulated to adjust the threshold voltage. In this case, a semiconductor work function stays the same because a same semiconductor substrate is used. Also, the capacitance of the silicon depletion layer and the potential to equalize a shift in Fermi level from intrinsic to doped are unchanged.

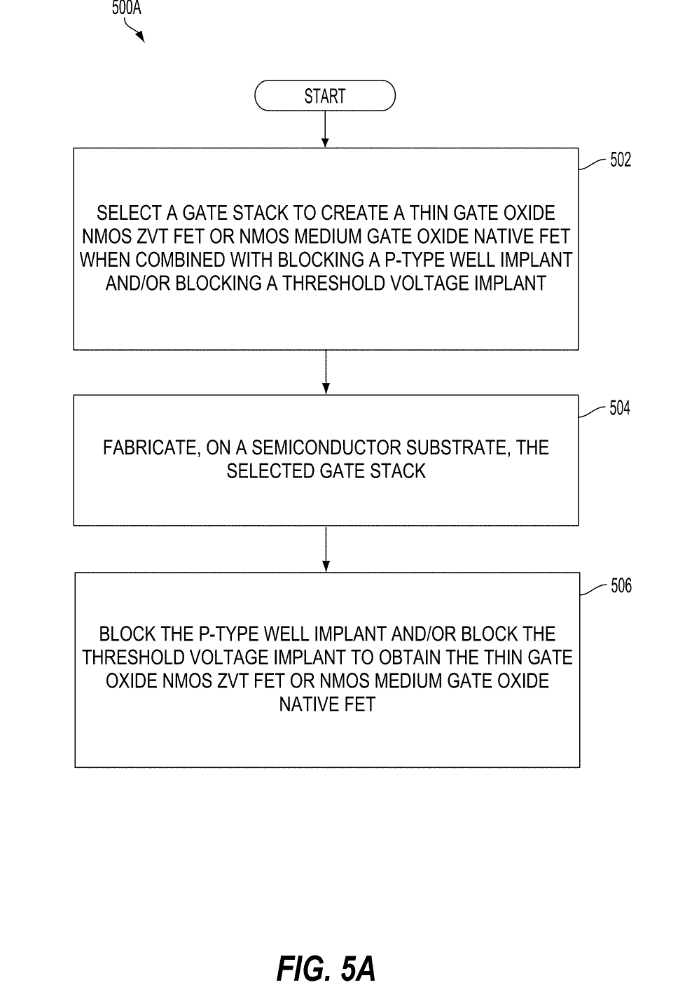

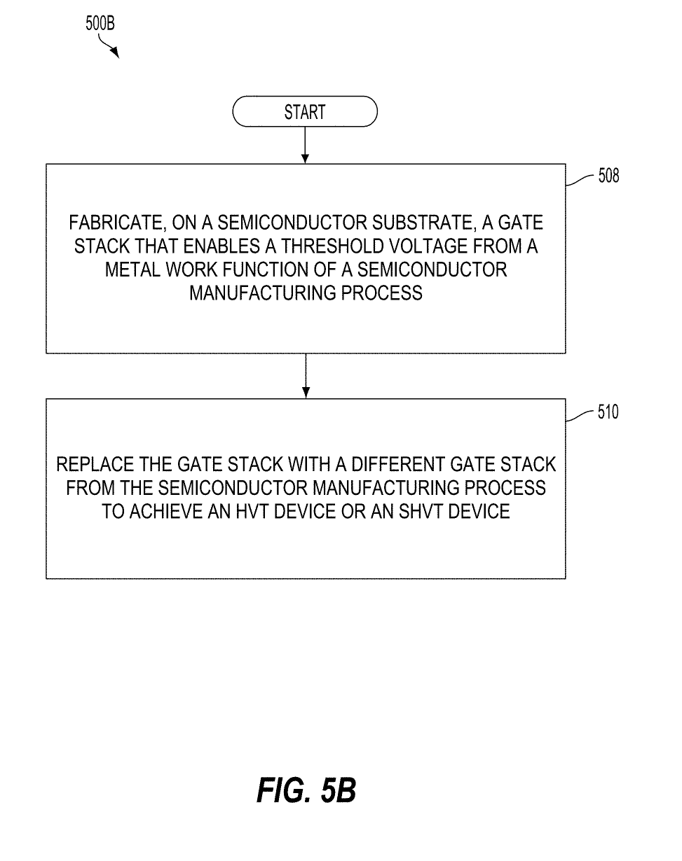

FIG. 5A depicts a simplified flowchart of a method 500A of manufacturing a thin gate oxide N-type metal-oxide-semiconductor (NMOS) zero threshold voltage (ZVT) field effect transistor (FET) and an NMOS medium gate oxide native FET with a semiconductor manufacturing process. At block 502, a gate stack is selected to create the thin gate oxide NMOS ZVT FET or NMOS medium gate oxide native FET when combined with blocking a P-type well implant and/or blocking a threshold voltage implant. At block 504, the selected gate stack is fabricated on a semiconductor substrate. At block 506, the P-type well implant and/or the threshold voltage implant are blocked to obtain the thin gate oxide NMOS ZVT FET or NMOS medium gate oxide native FET.

FIG. 5B depicts a simplified flowchart of a method 500B of manufacturing a high threshold voltage device (HVT) device or a super high threshold voltage (SHVT) device. At block 508, a gate stack that enables a threshold voltage from a metal work function of a semiconductor manufacturing process is fabricated on a semiconductor substrate. At block 510, the gate stack is replaced with a different gate stack from the semiconductor manufacturing process to achieve the HVT device or the SHVT device.

FIG. 6 is a block diagram showing an exemplary wireless communication system in which a configuration of the disclosure may be advantageously employed. For purposes of illustration, FIG. 6 shows three remote units 620, 630, and 650 and two base stations 640. It will be recognized that wireless communication systems may have many more remote units and base stations. Remote units 620, 630, and 650 include IC devices 625A, 625B, and 625C that include the disclosed transistor or device. It will be recognized that other devices may also include the disclosed transistor, such as the base stations, switching devices, and network equipment. FIG. 6 shows forward link signals 680 from the base station 640 to the remote units 620, 630, and 650 and reverse link signals 690 from the remote units 620, 630, and 650 to base station 640.

In FIG. 6, remote unit 620 is shown as a mobile telephone, remote unit 630 is shown as a portable computer, and remote unit 650 is shown as a fixed location remote unit in a wireless local loop system. For example, a remote unit may be a mobile phone, a hand-held personal communication systems (PCS) unit, a portable data unit such as a personal digital assistant (PDA), a GPS enabled device, a navigation device, a set top box, a music player, a video player, an entertainment unit, a fixed location data unit such as a meter reading equipment, or other communications device that stores or retrieves data or computer instructions, or combinations thereof. Although FIG. 6 illustrates remote units according to the aspects of the disclosure, the disclosure is not limited to these exemplary illustrated units. Aspects of the disclosure may be suitably employed in many devices, which include the transistor.

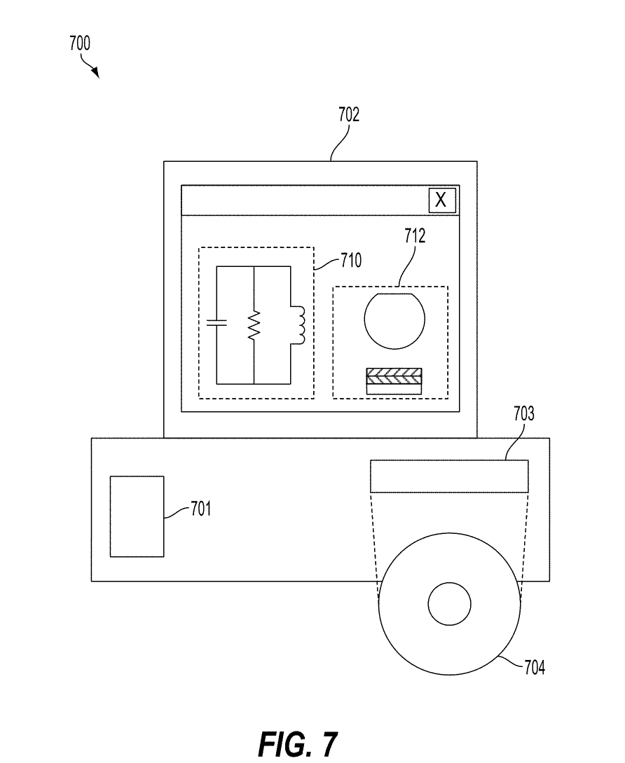

FIG. 7 is a block diagram illustrating a design workstation used for circuit, layout, and logic design of the transistor disclosed above. A design workstation 700 includes a hard disk 701 containing operating system software, support files, and design software such as Cadence or OrCAD. The design workstation 700 also includes a display 702 to facilitate design of a circuit 710 or a transistor. A storage medium 704 is provided for tangibly storing the design of the circuit 710 or the transistor. The design of the circuit 710 or the transistor may be stored on the storage medium 704 in a file format such as GDSII or GERBER. The storage medium 704 may be a CD-ROM, DVD, hard disk, flash memory, or other appropriate device. Furthermore, the design workstation 700 includes a drive apparatus 703 for accepting input from or writing output to the storage medium 704.

Data recorded on the storage medium 704 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 704 facilitates the design of the circuit 710 or the transistor by decreasing the number of processes for designing semiconductor or passive wafers.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

Although the present disclosure and its advantages have been described in detail, it should be understood that various changes, substitutions and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, and composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

What is claimed is:

1. A method of manufacturing a thin gate oxide N-type metal-oxide-semiconductor (NMOS) zero threshold voltage (ZVT) field effect transistor (FET) and an NMOS medium gate oxide native FET with a semiconductor manufacturing process, comprising:
selecting a gate stack to create the thin gate oxide NMOS ZVT FET or the NMOS medium gate oxide native FET when combined with blocking a P-type well implant and/or blocking a threshold voltage implant;
fabricating, on a semiconductor substrate, the selected gate stack; and
blocking the P-type well implant and/or blocking the threshold voltage implant to obtain the thin gate oxide NMOS ZVT FET or the NMOS medium gate oxide native FET.

2. The method of claim 1, in which the gate stack comprises a high-k metal gate stack.

3. The method of claim 1, in which each of the thin gate oxide NMOS ZVT FET and the NMOS medium gate oxide native FET comprises a finFET.

4. The method of claim 1, in which the blocking comprises blocking the P-type well implant and/or blocking the threshold voltage implant from the NMOS medium gate oxide native FET.

5. The method of claim 4, further comprising adding a mask of the NMOS medium gate oxide native FET for a low doped drain of the NMOS medium gate oxide native FET.

6. The method of claim 1, in which selecting the gate stack to create the thin gate oxide NMOS ZVT FET or the NMOS medium gate oxide native FET comprises selecting a metal work function (MWF) metal and a gate conductor stack that enables a lowest threshold voltage from a lowest metal work function of the semiconductor manufacturing process that includes a plurality of gate stacks with different threshold voltages.

7. The method of claim 6, further comprising sharing a low doped drain of the selected gate stack without introducing additional masks or introducing a new low doped drain mask to independently control a threshold voltage.

8. The method of claim 6, in which the gate stack that enables the lowest threshold voltage from the lowest metal work function comprises a gate stack of an N-type analog low threshold voltage (ALVTN) device.

9. The method of claim 6, in which the blocking comprises blocking the P-type well implant and/or blocking the threshold voltage implant from an N-type analog low threshold voltage (ALVTN) device.

10. A method of manufacturing an HVT device (high threshold voltage device) or a SHVT device (super high threshold voltage device), comprising:
fabricating, on a semiconductor substrate, a gate stack that enables a threshold voltage from a metal work function of a semiconductor manufacturing process; and
replacing the gate stack with a different gate stack from the semiconductor manufacturing process to obtain the HVT device or the SHVT device.

11. The method of claim 10, in which achieving the HVT device comprises achieving an N-type HVT (HVTN) device starting with an ALVTN device (N-type analog low threshold voltage device).

12. The method of claim 11, in which the replacing further comprises replacing a gate stack of the ALVTN device with a gate stack of a P-type regular threshold voltage (RVTP) device.

13. The method of claim 10, in which achieving the HVT device comprises achieving a P-type HVT (HVTP) device starting with an RVTP device (P-type regular threshold voltage device).

14. The method of claim 13, in which the replacing further comprises replacing a gate stack of the RVTP device with a gate stack of an N-type regular threshold voltage (RVTN) device.

15. The method of claim 10, in which achieving the SHVT device comprises achieving an N-type SHVT (SHVTN) device starting with an ALVTN device (N-type analog low threshold voltage device).

16. The method of claim 15, in which the replacing and in which the replacing further comprises replacing a gate stack of the ALVTN device with a gate stack of a P-type analog low threshold voltage (ALVTP) device.

17. The method of claim 10, in which achieving the SHVT device comprises achieving a P-type SHVT (SHVTP) device starting with an RVTP device (P-type regular threshold voltage device).

18. The method of claim 17, in which the replacing further comprises replacing a gate stack of the RVTP device with a gate stack of a P-type analog low threshold voltage (ALVTP) device.

19. The method of claim 10, in which the HVT device or the SHVT device is achieved without additional masks.

20. The method of claim 10, in which each of the HVT device or the SHVT device comprises a finFET.
